(19) United States
(12) Patent Application Publication
(10) Pub. No.: US 2022/0322493 A1
(43) Pub. Date: Oct. 6, 2022

(54) HEATING ELEMENT FOR DIN RAIL

(71) Applicant: Swerail AB, Västerås (SE)

(72) Inventors: Ulf HOLGERSSON, Västerås (SE); Fredrik GRIVANS, Västerås (SE)

(21) Appl. No.: 17/608,779

(22) PCT Filed: May 6, 2020
(86) PCT No.: PCT/EP2020/062560

§ 371 Date: Nov. 4, 2021

(30) Foreign Application Priority Data
May 7, 2019 (SE) 1950543-7

(51) Int. Cl. H05B 3/12; H05B 3/36

(52) U.S. Cl. CPC H05B 3/12; H05B 3/36; H05B 2203/02; H05B 2203/013

(57) ABSTRACT

The present disclosure relates to a heating element (5) for heating electrical equipment mounted on a DIN rail (1). The heating element (5) comprises an elongated flexible sheet (11) made of an electrically insulating material and a layer comprising Positive Temperature Coefficient paint (12) disposed on an upper surface (11a) of the flexible sheet (11). A method for mounting the heating element (5) to a DIN rail is provided. The method comprises bending the flexible sheet (11) such that an inverted U-shape is formed along the length of the flexible sheet and inserting the heating element (5) into a groove of the DIN rail (1) such that the bent flexible sheet stays in position by spring force of the bend. A use of the heating element for heating a DIN rail is also provided.

### TECHNICAL FIELD

The present invention relates to a heating element for heating a DIN rail, a method for mounting the heating element and use of the heating element with a DIN rail.

### BACKGROUND

DIN rails are used for mounting circuit breakers and control equipment in racks. They are commonly made from cold rolled carbon steel sheet and can have a zinc-plated or chromated bright surface finish. The DIN rail is for mechanical support of the circuit breakers and control equipment.

There are three major types of DIN rail: Top hat rail, C-section rail and G-section rail. And within these types, there are many variations, some of which are:
Top hat rail IEC/EN 60715—35×7.5. It is known as the TS35 rail in the US
Top hat rail IEC/EN 60715—35×15. It is also known as the TS35 rail in the US
5 mm×7.5 mm top-hat rail (EN 50022, BS 5584, DIN 46277-3)
Miniature top-hat rail, 15 mm×5.5 mm (EN 50045, BS 6273, DIN 46277-2)
75 mm wide top-hat rail (EN 50023, BS 5585)
C20 (The number suffix corresponds to the overall vertical height of the rail: e.g.: AS 2756.1997(C3)
C30
C40
C50
EN 50035 (G32 in the US), BS 5825, DIN 46277-1

The DIN rails are all elongated rails with an elongated flat back part that is to be fastened to a suitable surface. They also have two protrusions on the upper and lower side of the elongated flat back part for mounting electrical equipment. The protrusions have different shapes and dimensions for the different types. Different cross sections of DIN rails are illustrated in FIGS. 1 to 3. FIG. 1 illustrates a Top hat rail, FIG. 2 a C-section rail and FIG. 3 a G-section rail.

A problem in rack cabinets, especially those who are located outdoors, is the varying temperature in the cabinets. Circuit breakers are designed to break the current to a circuit at exceedance of a predetermined Ampere. If the temperature in the cabinet gets very low, the circuit breakers may malfunction and break the current at much higher load than specified, i.e. at higher Amperage.

Another problem is that systems located in cold environments often accumulate condensation, which can damage electronic components.

A solution for the above is to put an electric heater inside the cabinet with a temperature controller so that that a desired temperature can be maintained in the cabinet.

### SUMMARY

It is an aim of the present invention to at least partly overcome the above problems, and to provide an improved way to avoid condensation around electrical equipment in cabinets, to maintain a good working temperature for the electrical equipment as well as saving energy.

The present disclosure aims to provide a heating element for heating a DIN rail, a method for mounting the heating element on a DIN rail and use of the heating element with a DIN rail.

This aim is achieved by the heating element as defined in claim 1 and the method of mounting as defined in claim 10 and the use of the heating element as defined in claim 11.

According to some aspects of the disclosure, it provides a heating element for heating electrical equipment mounted on a DIN rail. The heating element comprises an elongated flexible sheet made of an electrically insulating material and a layer comprising Positive Temperature Coefficient, PTC, paint disposed on an upper surface of the flexible sheet. The heating element is used to heat electrical equipment mounted on a DIN rail and it also heats the DIN rail itself. By heating the electrical equipment and by having the heating elements so close to the electrical equipment, there is no need to heat the whole rack cabinet to avoid condensation and malfunctioning of circuit breakers. In other words, the circuit breakers are heated by the heating element and thus, there is no need for heating the cabinet and energy is saved. Since Positive Temperature Coefficient paint is used, there is also no need for any additional circuitry for controlling the temperature due to the self-limiting nature of PTC paint.

It should be noted that the feature that the layer comprising PTC paint is disposed on an upper surface of the flexible sheet includes a layer of PTC paint directly disposed on the upper surface as well as a layer of PTC paint disposed on the upper surface with one or more layers of other material therebetween; such as an adhesive or insulating material. In other words, a layer of PTC paint disposed on the upper surface can be disposed directly on the upper surface or with one or more layers therebetween.

According to some aspects, the Positive Temperature Coefficient paint is disposed over substantially the full length of the flexible sheet. The flexible sheet can thus heat electrical equipment over its full length.

According to some aspects, the Positive Temperature Coefficient paint is disposed over a width of the flexible sheet of at least 2 mm and on a central part of the flexible sheet. The heating element will be located with its upper surface towards the electrical equipment. Having the Positive Temperature Coefficient paint arranged on the central part of the flexible sheet and along the length of it will provide good heating to the electrical equipment to be mounted on the DIN rail.

According to some aspects, the Positive Temperature Coefficient paint is disposed over at least 75% of the width of the flexible sheet and on a central part of the flexible sheet. How much of the upper surface is covered by the paint depends on how much heat one wants to achieve, which may be different for different types of users and regions.

According to some aspects, the Positive Temperature Coefficient paint is disposed on multiple discrete places on the upper surface of the flexible sheet. This may have the advantage of a more even temperature across the heating element since several smaller Positive Temperature Coefficient paint spots are easier to heat than one large part. It is easier to achieve an even current to smaller dots of Positive Temperature Coefficient paint than one larger area of paint.

According to some aspects, the electrically insulating material comprises a dielectric material such as polyester or plastic. Polyester and plastic are both cheap materials that are easy to handle and shape.

According to some aspects, the flexible sheet comprises one edge along each side of the flexible sheet and the edges on the two elongated sides are rounded on the side of the upper surface. The rounded edge is so that the heating element fits better in DIN rails which are rounded between the protrusions and the flat back.

According to some aspects, the length and width of the flexible sheet are adapted such that the flexible sheet, when it is bent in an inverted U-shape along its length, fits into a groove of a DIN rail.

According to some aspects, the heating element comprises wiring for powering the Positive Temperature Coefficient paint arranged in connection to the Positive Temperature Coefficient paint.

According to some aspects of the disclosure, it provides a method for mounting the heating element according to above to a DIN rail, comprising bending the flexible sheet such that an inverted U-shape is formed along the length of the flexible sheet, and inserting the heating element into a groove of the DIN rail such that the bent flexible sheet stays in position by spring force of the bend.

According to some aspects of the disclosure, it provides a use of the heating element according to above for heating a DIN rail, wherein the heating element is mounted in the DIN rail by bending the flexible sheet in an inverted U-shape along its length and arranging it into a groove of a DIN rail such that the bent flexible sheet stays in position by spring force of the bend.

According to an alternative embodiment of the disclosure, it comprises a DIN rail for mounting of electrical equipment. The DIN rail comprises an elongated support section with a back side and a front side, wherein the front side comprises two elongated mounting flanges along opposite sides of the front side, for fastening the electrical equipment, and an elongated groove therebetween. The DIN rail comprises at least one heating element arranged in direct contact with the support section and the at least one heating element comprises at least one Positive Temperature Coefficient, PTC, heater. Electrical equipment mounted on the DIN rail will be heated both through thermal radiation from the heaters and the DIN rail and by thermal conductivity through the DIN rail. By heating the DIN rail and by having the heating elements so close to the electrical equipment, there is no need to heat the whole rack cabinet to avoid condensation and malfunctioning circuit breakers. In other words, the circuit breakers are heated by the heated DIN rail and thus, there is no need for heating the cabinet and energy is thus saved. Since PTC heaters are used, there is also no need for any additional circuitry for controlling the temperature due to the self-limiting nature of PTC heaters.

Different aspects of the alternative embodiment are hereinafter described.

According to some aspects, the at least one heating element is arranged in the groove. When positioned in the groove, the heating elements are physically protected by the mounting flanges and the support section.

According to some aspects, the at least one heating element comprises a material surrounding the at least one Positive Temperature Coefficient heater, the material comprises silicone and has an outer shape such that it fits into the groove and is held in the groove by the mounting flanges. Silicone is a flexible material and it is therefore possible to put the heating element in the grove by pushing it in. The silicone will deform slightly at the edges to hold the heating element in place. This is a very efficient way to fasten the heating elements.

According to some aspects, the at least one heating element is fastened to the support section in the groove by means of at least one resilient element, the at least one resilient element being clamped between the two opposing mounting flanges such that it holds the at least one heating element in place in the groove. By using a resilient element, the heating elements may be attached in the groove instantly. This is also a cheap and fast way of securing the heating element.

According to some aspects, the at least one heating element is fastened to the support section by means of an adhesive. There are very strong adhesives and an adhesive is a fast and cheap way of attaching the heating elements to the support section.

Both using an adhesive and a resilient element for fastening the heating element may be used in an efficient way in mass producing the DIN rail.

According to some aspects, the at least one heating element comprises wiring for powering the at least one Positive Temperature Coefficient heater, the wiring being arranged in the groove. An advantage with this is that the wiring is physically protected in the groove by the mounting flanges. The wiring is thus protected from physical damage and from getting hooked on something during handling. Another advantage is that it is visually appealing to hide the wiring in the grove such that they are visually less apparent.

According to some aspects, the at least one heating element is attached to the back side of the support section. For simplifying mass production of the Din rail, the heating element may be attached to the back side of the support section. This may also be advantageous depending on the type of standard used for the DIN rail. For some standards, the heating element may be in the way of mounting the electronic equipment when located in the groove. In such cases, arranging the heating elements on the back side is advantageous.

According to some aspects, the at least one heating element is embedded in the material of the support section. This is advantageous especially in demanding environments where the heating elements and/or the wiring needs to be protected from the environment. This may also be a very secure alternative since a user of the DIN rail will not be able to access the heating element or its wiring.

According to some aspects, the at least one heating element comprises a plurality of heating elements arranged at a distance from each other along the elongated support section. DIN rails come at different lengths and they usually have holes at regular intervals in the support section for fastening to a surface using for example screws or the like. The heating elements may therefore be distributed with a distance between them so that the holes are accessible for fastening the rail.

According to some aspects, the plurality of heating elements are evenly distributed along a length of the elongated support section. That the heating elements are evenly distributed may be advantageous in production, since there is no resetting of the distances, and it may also be visually appealing with regular intervals between the heating elements.

According to some aspects, each of the at least one heating element comprises a plurality of Positive Temperature Coefficient heaters distributed in the heating element. PTC elements can be produced in various sizes and shapes and each heating element may therefore comprise one or several PTC heaters 6. For simplifying production, it may be advantageous with one PTC heater per heating element but more than one may give a more even spread of heat.

According to some aspects, the Positive Temperature Coefficient heaters are evenly distributed along a length of the heating element. An advantage with this is even heat distribution in the heating element.

According to some aspects, the Positive Temperature Coefficient heaters are arranged between two steel plates which are arranged along a length of the heating element, the Positive Temperature Coefficient heaters and the steel plates being embedded in an electrically insulating material.

According to some aspects, the at least one heating element has a maximum surface temperature between 30° and 45° Celsius and preferably a maximum temperature of 40° Celsius. The temperature is to ensure a good working temperature for electrical equipment mounted on the DIN rail. Electrical equipment is usually made for functioning best in room temperature or slightly above room temperature. A surface temperature between 30 and 45 degrees Celsius will provide optimal working conditions for the electrical equipment.

According to an embodiment of the disclosure, it comprises the use of the DIN rail according to any of the above features, to heat mounted electrical equipment.

According to an embodiment of the disclosure, it comprises a DIN rail system comprising a DIN rail according to any of the above alternative features, the system comprising a circuit breaker mounted to the DIN rail and electrically connected to the at least one heating element. With a circuit breaker for the at least one heating element already attached to the DIN rail, the DIN rail system provides a ready to use DIN rail which provides optimal working conditions for electrical equipment. The DIN rail system is thus easy to mount to a surface and connecting electricity to the circuit breaker.

According to some aspects, the circuit breaker is a miniature circuit breaker, MCB.

### BRIEF DESCRIPTION OF THE DRAWINGS

The invention will now be explained more closely by the description of different embodiments of the invention and with reference to the appended figures.

FIG. 1 illustrates a cross section of a Top hat rail

FIG. 2 illustrates a cross section of a C-section rail and

FIG. 3 illustrates a cross section of a G-section rail

FIG. 4 illustrates a heating element comprising an elongated sheet

FIG. 5 illustrates the heating element from the side when it is bent to an inverted U-shape

FIG. 6 illustrates a DIN rail with a heating element arranged in its groove

FIG. 7 illustrates the same as FIG. 6 from a side view

FIG. 7′ illustrates the same as FIG. 7 but where the DIN rail is a G-section rail

FIG. 8 illustrates a heating element arranged in the groove of a DIN rail and with piece of electrical equipment mounted on the DIN rail

FIG. 9 illustrates an exploded view of the arrangement of FIG. 8

FIG. 10 illustrates flexible insulating material under printed wiring and PTC paint

FIG. 11 illustrates a cross section of a part of FIG. 10 showing a PTC paint patch, wiring and encapsulation

FIG. 12 illustrates an example DIN rail comprising heating elements arranged in the groove viewed from above

FIG. 13 illustrates the DIN rail of FIG. 10 from the side

FIG. 14 illustrates a cross section of the DIN rail of FIGS. 4 and 5

FIG. 15 illustrates a cross section of an example DIN rail where the heating element is snapped into the groove

FIG. 16 illustrates the DIN rail of FIGS. 4, 5 and 6 from a perspective view

FIG. 17 illustrates a cross section of an example DIN rail with an embedded heating element

FIG. 18 illustrates a cross section of an example heating element

### DETAILED DESCRIPTION

Aspects of the present disclosure will be described more fully hereinafter with reference to the accompanying drawings. The device disclosed herein can, however, be realized in many different forms and should not be construed as being limited to the aspects set forth herein. Like numbers in the drawings refer to like elements throughout.

The terminology used herein is for the purpose of describing particular aspects of the disclosure only and is not intended to limit the invention. As used herein, the singular forms “a”, “an” and “the” are intended to include the plural forms as well, unless the context clearly indicates otherwise.

Unless otherwise defined, all terms used herein have the same meaning as commonly understood by one of ordinary skill in the art to which this disclosure belongs.

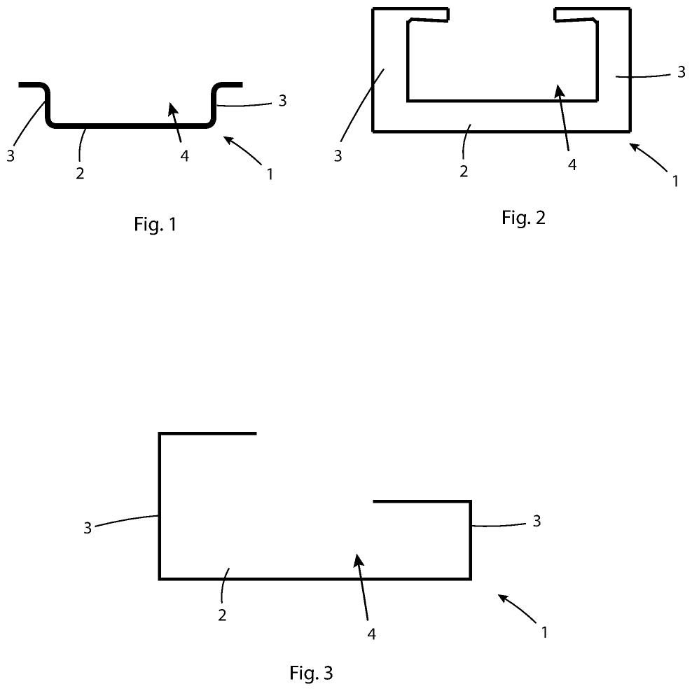

As discussed in the background section, different cross sections of DIN rails 1 are illustrated in FIGS. 1 to 3. FIG. 1 illustrates a Top hat rail, FIG. 2 a C-section rail and FIG. 3 a G-section rail. DIN rails 1 are typically made from cold rolled carbon steel sheet with a zinc-plated or chromated bright surface finish. Although metallic, they are meant only for mechanical support, and are not used as a bulbar to conduct electric current, although they may provide a chassis grounding connection.

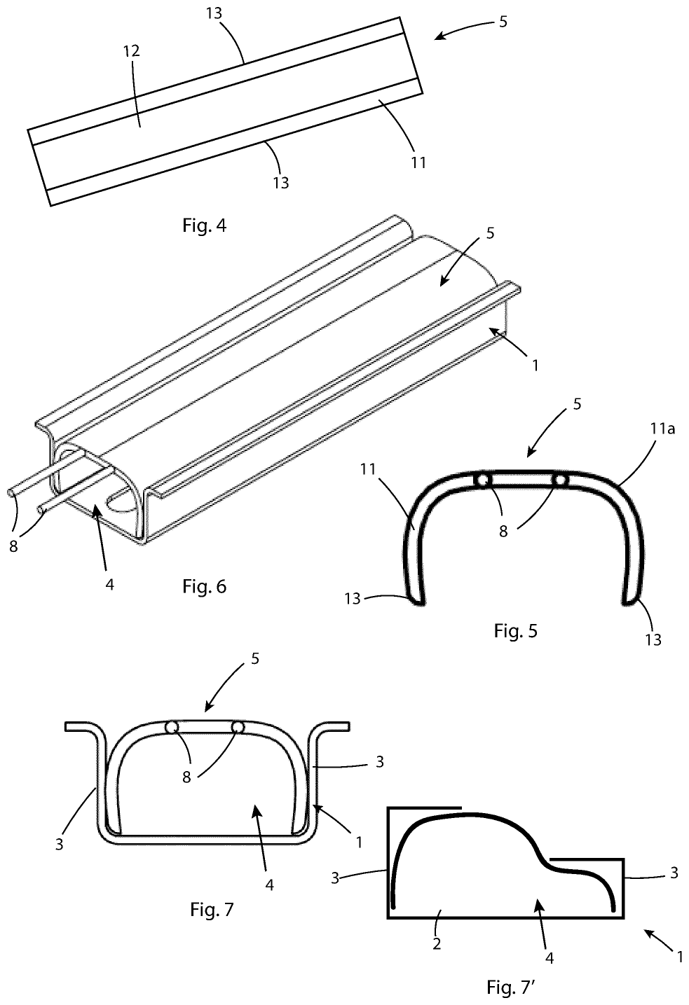

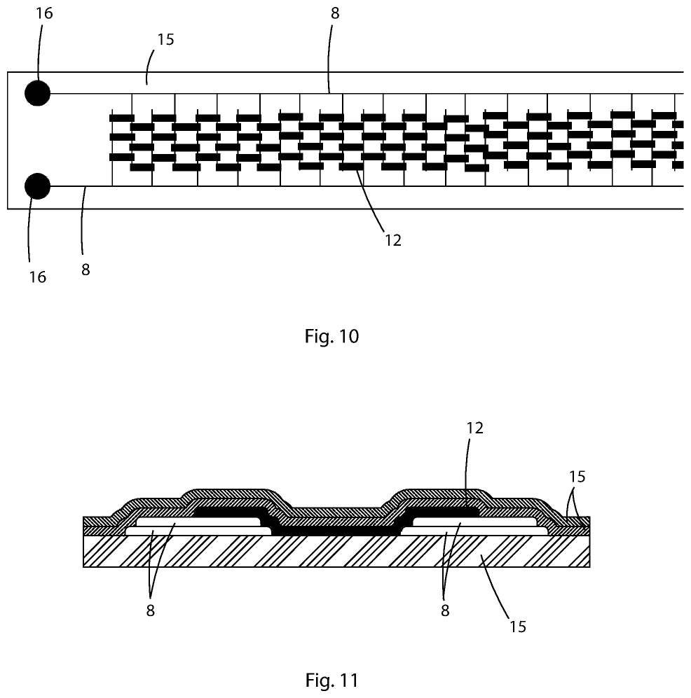

It should be noted that two alternative solutions are presented herein. One in connection to FIGS. 4 to 9, and one in connection to FIGS. 10 to 16. It should be noted that many aspects are applicable to both alternatives.

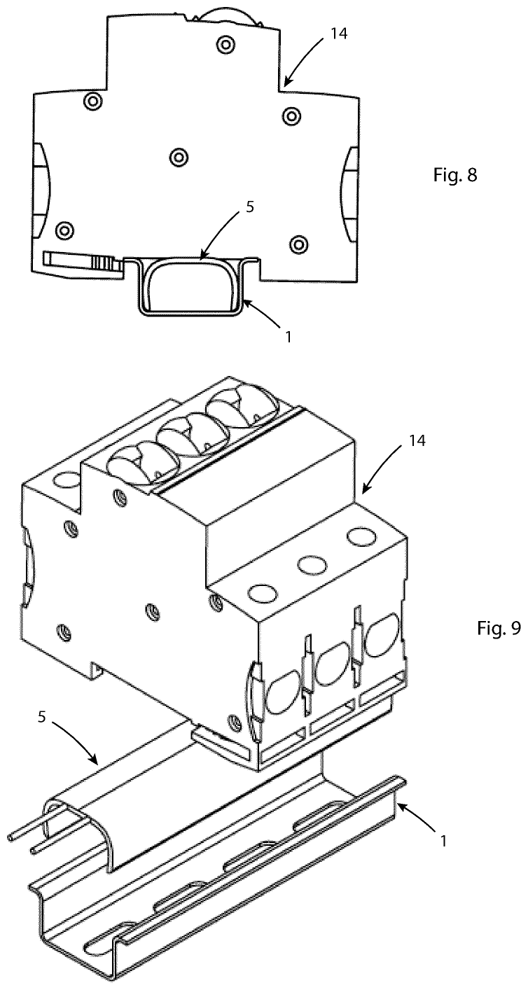

FIG. 4 illustrates a heating element 5 comprising an elongated sheet 11. According to some aspects of the disclosure, it provides a heating element 5 for heating electrical equipment mounted on a DIN rail 1. The heating element 5 comprises an elongated flexible sheet 11 made of an electrically insulating material and a layer comprising Positive Temperature Coefficient paint 12 disposed on an upper surface 11a of the flexible sheet 11. Positive Temperature Coefficient paint 12 comprises for example silicon or polymers blended with carbon. PTC paint is available from several manufacturers and its specific content is not disclosed herein. Example electrical equipment can be seen in FIGS. 8 and 9 where it is illustrated as a circuit breaker. Electrical equipment is for example circuit breakers, industrial control equipment and the like, adapted to be mounted on a DIN rail 1.

A DIN rail 1 comprises, as can be seen in FIGS. 1-3, an elongated support section 2 with a back side and a front side, wherein the front side comprises two elongated mounting flanges 3 along opposite sides of the front side, for fastening the electrical equipment, and an elongated groove 4 therebetween. In other words, the DIN rail 1 has first and second mounting flanges 3 extending lengthwise along opposite sides of the support section 2. In the examples of different DIN rail standards, these features are common for all standards.

The elongated flexible sheet may have a the slightly bent around a central line along the elongated shape. The heating element 5 is to be inserted into the groove 4 of a DIN rail and when it is inserted, it will have the inverted U-shape as shown in FIG. 5. The upper surface 11a of the heating element 5 is arranged upwards, away from the DIN rail, when the heating element is mounted in the DIN rail. FIG. 5 illustrates the heating element from the side when it is bent to an inverted U-shape. To make the insertion of the heating element easier to a user, it may be slightly pre-bent towards this shape. The elongated flexible sheet has a shape such that when it is inserted into the DIN rail, the legs of the U-shape presses against the DIN rail and holds the heating element 5 in place in the DIN rail. The elongated flexible sheet is flexible such that when arranged in the DIN rail, the legs of the U-shape presses against the DIN rail and holds the heating element 5 in place in the DIN rail. It should be noted that the flexible sheet may be pre-bent with a sharper angle than the angle illustrated in FIG. 5 as long as the legs of the U-shape are pressed towards each other when put in a DIN rail.

The heating element 5 is used to heat electrical equipment mounted on a DIN rail 1 and it also heats the DIN rail itself. By heating the electrical equipment and by having the heating elements so close to the electrical equipment, there is no need to heat the whole rack cabinet to avoid condensation and malfunctioning circuit breakers. In other words, the circuit breakers are heated by the heater and thus, there is no need for heating the cabinet and energy is saved. Since Positive Temperature Coefficient paint is used, there is also no need for any additional circuitry for controlling the temperature due to the self-limiting nature of the PTC paint.

An advantage with using Positive Temperature Coefficient paint 12, i.e. PTC paint 12, is that no temperature sensors are needed to turn the heat on and off to keep the desired heat. PTC paint 12 is a resistive heater and when PTC paint 12 reaches a certain temperature, the resistance increases so much that it is no longer heating up. In other words, a PTC material is designed to reach a maximum temperature, since at a predefined temperature, any further increase in temperature would be met with greater electrical resistance. PTC materials are thus inherently self-limiting in temperature so that there is no risk of the heating element 5 overheating. A PTC material does not get any hotter than the temperature where the resistance of the material increases rapidly. It is thus impossible for the PTC material to get hotter than the temperature it was manufactured for.

PTC paint 12 is manufactured to have a predefined maximum temperature. The PTC paint 12 is therefore chosen beforehand on what maximum temperature it is designed for.

According to some aspects, the Positive Temperature Coefficient paint 12 is disposed over substantially the full length of the flexible sheet. The flexible sheet can thus heat electrical equipment over its full length. If the PTC paint 12 is disposed over the full length or not is up to the designer. The PTC paint is the heating part of the heating element 5 but it will not matter if there is a part of the heating element that has no PTC paint 12 because that part will then simply not heat anything. The most efficient heating element heat-wise, is a heating element 5 with PTC paint across its full length.

According to some aspects, the Positive Temperature Coefficient paint 12 is disposed over a width of the flexible sheet 11 of at least 2 mm and on a central part of the flexible sheet 11. The PTC paint will be located with its upper surface towards the electrical equipment. Having the PTC paint arranged on the central part of the flexible sheet and along the length of it will provide good heating to the electrical equipment to be mounted on the DIN rail. With central part is meant the part of the upper surface of the flexible sheet that is in the middle of the flexible sheet width-wise and which extends the full length of the flexible sheet. In the example explained below in connection to FIG. 7′, it may be that the PTC paint is slightly offset from the central part so that the PTC paint is the part of the heating element that protrudes between the mounting flanges. There are many alternatives on how the PTC paint 12 can be arranged on the flexible sheet 11. A PTC paint with a high maximal temperature may be disposed on a narrower part of the upper surface may give the same amount of heat to the electrical equipment as PTC paint on a wider part of the upper surface 11a. The thickness of the PTC paint also influences the heat that the electrical equipment experiences. Since the temperatures required are depending on what environment the heating element is to be used in, the width and thickness of the PTC paint may be varied between uses. According to some aspects, the Positive Temperature Coefficient paint is disposed over a width of the flexible sheet 11 of at least 7 or 10 mm and on a central part of the flexible sheet 11. Again, how much of the upper surface is covered by the paint depends on how much heat one wants to achieve, which may be different for different types of uses and regions. The width of the PTC paint may also depend on the efficiency of the chosen PTC paint. Some PTC paints are more efficient than others. According to some aspects, the Positive Temperature Coefficient paint 12 is disposed over at least 50% or 75% of the width of the flexible sheet 11 and on a central part of the flexible sheet 11.

According to some aspects, the PTC paint 12 is disposed on multiple discrete places on the upper surface of the flexible sheet 11. This may have the advantage of a more even temperature across the heating element since several smaller Positive Temperature Coefficient paint spots are easier to heat than one large part. It is easier to achieve an even current to smaller dots of Positive Temperature Coefficient paint than one larger area of paint.

It should be noted that the PTC paint does not need to be arranged directly on the surface of the flexible sheet 11. There may be, for example, a layer of plastic, or other flexible insulating material therebetween. According to some aspects, the PTC paint is applied onto a flexible insulating material which is put onto the flexible substrate 11, for example by gluing or by tape or the like. According to some aspects, the PTC paint and wiring for power supply are encapsulated in a flexible insulating material and forms a unit which it then attached to the flexible sheet 11.

The thickness of the PTC paint is, according to some aspects, between 0.1 and 2 mm. Preferably, the thickness is between 0.1 and 1 mm.

According to some aspects, the electrically insulating material comprises a dielectric material such as polyester or plastic. Polyester and plastic are both cheap materials that are easy to handle and shape. The electrically insulating material is a non-conductive material.

Some DIN rails are more rounded where the front side and the mounting flanges meet than others. To accommodate for such differences, so that the heating element can be mounted in DIN rails of different shapes with a better fit, the flexible sheet may have rounded edges. According to some aspects, the flexible sheet 11 comprises one edge 13 along each side of the flexible sheet 11 and the edges on the two elongated sides are rounded on the side of the upper surface 11a. According to some aspects, the rounding has a radius that is the same as the diameter of the flexible sheet. The radius may also be smaller than the diameter. The radius may be chosen to be different to better fit different standards of DIN rails.

FIG. 6 illustrates a DIN rail with a heating element arranged in its groove. FIG. 7 illustrates the same as FIG. 6 from a side view. FIG. 7′ illustrates the same as FIG. 7 but where the DIN rail is a G-section rail. As can be seen in FIG. 7′, the heating element may also be used for DIN rails of different standards. According to some aspects, the length and width of the flexible sheet 11 are adapted such that the flexible sheet, when it is bent in an inverted U-shape along its length, fits into a groove of a DIN rail 1. Since there are many different DIN rail standards, the width cannot be specified more closely than that it should be adapted such that it can be arranged according to the above in a DIN rail. The width is thus decided when it is known which DIN rail the user will use. The length may also be varied depending on how long DIN rails are to be used. It should be noted that the heating element may protrude above the mounting flanges of the DIN rail. If it protrudes slightly, the PTC paint will be closer to the electrical equipment it is to heat which may be advantageous. However, the heating element should not be in the way of mounting new electrical equipment on the DIN rail.

FIG. 8 illustrates a heating element arranged in the groove of a DIN rail and with piece of electrical equipment 14 mounted on the DIN rail. FIG. 9 illustrates an exploded view of the arrangement of FIG. 8. As can be seen in the figures, the heating element 5, is arranged under the electrical equipment 14 in the groove 4 of a DIN rail 1. In the figure, the upper side of the flexible sheet abuts the electrical equipment 14, but it is not necessary, it is a possibility.

In FIGS. 5,6 and 7, example wiring 8 to power the PTC paint 12 is illustrated. According to some aspects, the heating element comprises wiring 8 for powering the Positive Temperature Coefficient paint 12 arranged in connection to the Positive Temperature Coefficient paint 12.

In the case that the PTC paint 12 is disposed on multiple discrete places on the upper surface of the flexible sheet 11, each dot, or spot, or patch of PTC paint is connected with the wiring 8. According to some aspects, the PTC paint is applied onto a flexible insulating material 15, as shown in FIGS. 10 and 11, together with the wiring 8 and then covered by flexible insulating material 15 to achieve flexible and insulating housing for the PTC paint and wiring. The encapsulated PTC paint and wiring is then put onto the flexible substrate 11. The PTC paint and wiring is for example printed onto the flexible sheet 11 or the flexible insulating material 15.

In FIGS. 10 and 11, flexible insulating material 15 is shown under printed wiring 8 and PTC paint 12. FIG. 10 illustrates flexible insulating material 15 under printed wiring 8 and PTC paint 12 and FIG. 11 illustrates a cross section of a part of FIG. 10 showing a PTC paint patch 12, wiring 8 and encapsulation 15. In these examples, the PTC paint 12 is disposed on multiple discrete places on the upper surface of the flexible sheet 11. In the illustrated example, the PTC paint is arranged in a pattern of PTC paint patterns.

As can be seen in FIG. 10, the wiring 8 has a grid design so that each PTC paint patch 12 is connected to + on one side and − on the other so that current run through each PTC paint patch. Example terminals 16 to connect to power supply is also illustrated. In FIG. 11, the layers are shown in a cross section. Flexible insulating material 15 has here been used to first print two layers of silver, the silver being the wiring 8, and then a layer of PTC paint 12. One layer of silver or more than two is also an alternative. The silver and PTC paint is then encapsulated by, in this example, two layers of flexible insulating material 15. The flexible insulating material 15 being, in the two top layers, for example, an electrically insulating flexible plastic. The flexible insulating material 15 in the first layer, i.e. the bottom layer, is for example Mylar polyester. The bottom layer and top layer of flexible insulating material may comprise the same material. The Encapsulation formed with the flexible insulating material 15 may also ensure that no moisture comes in contact with the wiring. The wiring 8 may comprise other materials than silver.

The example designs illustrated in FIGS. 10 and 11 is to be arranged on the flexible sheet 5 to form the heating element 1. An alternative is that the PTC paint 12 and the wiring 8 are printed directly on the flexible sheet 5 and then encapsulated by flexible insulating material 15. The illustrated examples work with all described variations of the flexible sheet 5.

The heating element is for example powered by riveting contacts at the terminals 16 which can be plugged in with a power supply. The contacts are for example riveted using a plastic housing over the contacts.

The disclosure also provides a method for mounting the heating element 5 according to any one of the above aspects, to a DIN rail. The method comprises bending the flexible sheet 11 such that an inverted U-shape is formed along the length of the flexible sheet and inserting the heating element 5 into a groove 4 of the DIN rail 1 such that the bent flexible sheet stays in position by spring force of the bend. In other words, the heating element 5, is bent along its length such that it can be pushed into the groove 4 of a DIN rail 1. When inserted, the resilience of the flexible material in the flexible sheet, will hold it in place. The flexible sheet 11 is thus resilient.

The bending of the flexible sheet 11 such that an inverted U-shape is formed along the length of the flexible sheet is done with the PTC paint at the upper surface, on the underside of the U, in the inverted U-shape, such that when the heating element is inserted into the groove 4 of the DIN rail, the PTC paint is arranged on the side of the heating element facing away from the DIN rail.

The disclosure also provides a use of the heating element according to any one of the aspects above, for heating a DIN rail, wherein the heating element is mounted in the DIN rail by bending the flexible sheet 11 in an inverted U-shape along its length and arranging it into a groove of a DIN rail 1 such that the bent flexible sheet 11 stays in position by spring force of the bend. Also here, the upper surface 11a is on the side of the bent heating element facing away from the DIN rail.

Please note that the layer of PTC paint 12 is illustrated in FIG. 4. In FIGS. 5-9, the PTC paint 12 is still there but not illustrated. The PTC paint 12 is always arranged on the side of the heating element 5 that faces the electrical equipment 14 when mounted in a DIN rail.

For ensuring secure functionality of the heating element 5, it may be connected to a circuit breaker for protecting it from overload or short circuit. According to an embodiment of the disclosure, it comprises a DIN rail system comprising a DIN rail 1 comprising an elongated support section 2 with a back side and a front side, wherein the front side comprising two elongated mounting flanges 3 along opposite sides of the front side 2, for fastening the electrical equipment 14, and an elongated groove 4 therebetween. A heating element 5 according to any one of the aspects above, is arranged in the groove 4 of the DIN rail in an inverted U-shape such that the upper surface 11a faces away from the DIN rail. The Din rail system comprises a circuit breaker mounted to the DIN rail 1 and electrically connected to the heating element 5. With a circuit breaker for the heating element 5 attached to the DIN rail 1, the DIN rail system provides a ready to use DIN rail 1 which provides optimal working conditions for electrical equipment. The DIN rail system is thus easy to mount to a surface and connecting electricity to the circuit breaker. The DIN rail 1 of the DIN rail system can of course be according to any of the above described aspects since all of the above are combinable with a circuit breaker. The circuit breaker is designed to be fastened to the protruding parts/mounting flanges of the DIN rail 1. According to some aspects, the circuit breaker is a miniature circuit breaker, MCB and it may also be a MCCB, Molded Case Circuit Breaker. One circuit breaker may also be connected to several heating elements arranged on several respective DIN rails in the same rack.

It should be noted that one length of a DIN rail may be heated with one or more heating elements according to above.

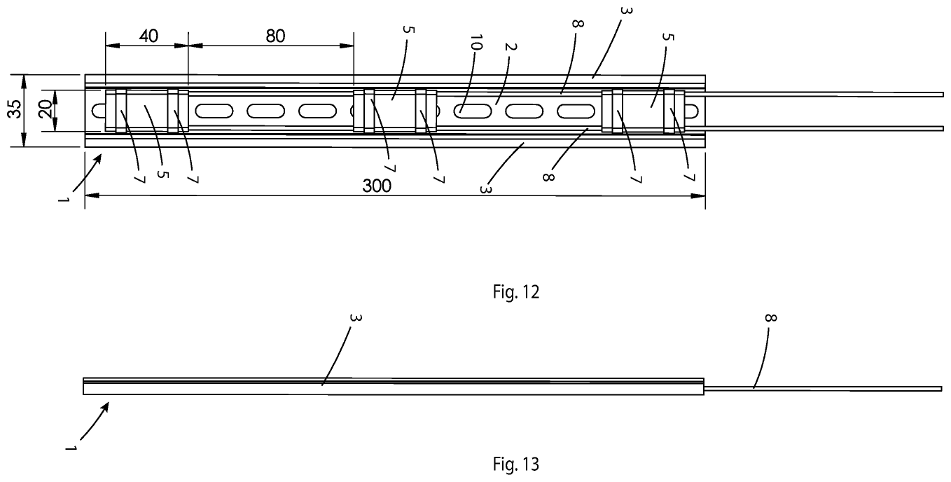

Below follows a description of the alternatives shown in FIGS. 12 to 18.

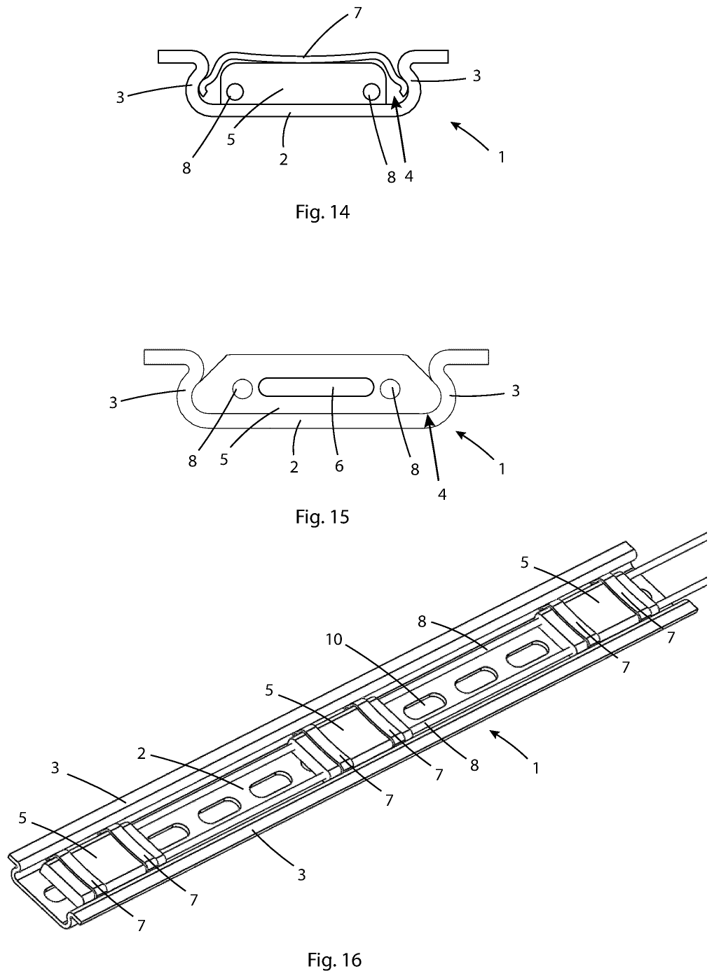

A DIN rail 1 for mounting of electrical equipment is disclosed. The DIN rail 1 comprises an elongated support section 2 with a back side and a front side, wherein the front side comprises two elongated mounting flanges 3 along opposite sides of the front side, for fastening the electrical equipment, and an elongated groove 4 therebetween. In other words, the DIN rail 1 has first and second mounting flanges 3 extending lengthwise along opposite sides of the support section 2. In the examples of different DIN rail standards, these features are common for all standards. As can be seen in FIGS. 1 to 3, as well as FIG. 14 which will be discussed below, the mounting flanges 3 are bent at some point to form a part that is parallel with the support section 2. Function and variations in shape and size of DIN rails 1 are common knowledge to a person skilled in the art and defined in the various standards discussed in the background section.

The DIN rail 1 presented in this disclosure comprises at least one heating element 5 arranged in direct contact with the support section 2 and the at least one heating element 5 comprises at least one Positive Temperature Coefficient heater 6. In other words, the support section 2 is heated by the heating elements 5 with Positive Temperature Coefficient, PTC, heaters. In other words, in the alternatives shown in FIGS. 12 to 18, the heating elements comprises PTC heaters in them, the PTC heaters are preferably in the form of PTC ceramic stones. Another difference from the above described features is that the heating element is here mounted in direct contact with the support section 2. When mounting electrical equipment on the DIN rail 1, the electrical equipment will be heated both through thermal radiation from the heaters and the DIN rail 1 and by thermal conductivity through the DIN rail 1. By heating the DIN rail 1 and by having the heating elements 5 so close to the electrical equipment, there is no need to heat the whole rack cabinet to avoid condensation and malfunctioning circuit breakers. In other words, the circuit breakers are heated by the heated DIN rail 1 and thus, there is no need for heating the cabinet and energy is thus saved. Since PTC heaters 6 are used, there is also no need for any additional circuitry for controlling the temperature due to the self-limiting nature of PTC heaters 6.

There are several alternatives to where to arrange the heating element/elements 5 in direct contact with the support section 2 which will be further described below.

An advantage with using Positive Temperature Coefficient heaters 6, i.e. PTC heaters 6, is that no temperature sensors are needed to turn the heat on and off to keep the desired heat. PTC heaters 6 are resistive heaters and when PTC heaters 6 reach a certain temperature, the resistance increases so much that it is no longer heating up. In other words, a PTC material is designed to reach a maximum temperature, since at a predefined temperature, any further increase in temperature would be met with greater electrical resistance. PTC materials are thus inherently self-limiting in temperature so that there is no risk of the heating element 5 overheating. A PTC material does not get any hotter than the temperature where the resistance of the material increases rapidly. It is thus impossible for the PTC material to get hotter than the temperature it was manufactured for.

PTC heaters 6 in the form of PTC ceramic stones are manufactured to have a predefined maximum temperature. The PTC heaters 6 are therefore chosen beforehand on what their maximum temperature is. The structure of the PTC heaters 6 will not be further discussed here since it is known to a person skilled in the art.

A PTC heater 6 in the form of PTC ceramic stones may be manufactured in many different sizes, for example around 20×15×2 mm. The PTC heaters 6 are for example between 3 and 40 mm long, between 1 and 25 mm wide and between 0.1 and 5 mm thick.

An example of a DIN rail 1 comprising a heating element 5 is illustrated in FIGS. 12 to 16. In the illustrated example the at least one heating element 5 is arranged in the groove 4. Electrical equipment is in general mounted on the mounting flanges 3. There is thus room for the heating element/elements 5 in the groove 4. When positioned in the groove 4, the heating at least one heating element is also physically protected by the mounting flanges 3 and the support section 2. In this example, the size and shape of the heating element 5 is such that it fits into the groove 4.

In FIGS. 12 to 16 the elongated support section 2 and the two elongated mounting flanges 3 can be seen.

In the cross section of FIG. 14, it can be seen that this example DIN rail 1 has a cross section slightly different from the DIN rails 1 of FIGS. 1 to 3. The mounting flanges 3 are more curved than those of the previous examples. The features presented in this disclosure are applicable to all DIN rail standards unless explicitly stated otherwise.

In the cross section of FIG. 15, an example way to fasten the heating element 5 in the groove is illustrated. According to some aspects, the at least one heating element 5 comprises a material surrounding the at least one Positive Temperature Coefficient heater 6, the material comprises silicone and has an outer shape such that it fits into the groove and is held in the groove 4 by the mounting flanges 3. Silicone is a flexible material and it is therefore possible to put the heating element in the grove by pushing it in. The silicone will deform slightly at the edges to hold the heating element in place. This is a very efficient way to fasten the heating elements. It may also be combined with any of the other ways to fasten it. To increase the thermal conductivity and the stiffness of the silicone it may be mixed with for example silicon. Other materials may be added to increase the thermal conductivity and/or the stiffness of the material.

One way to attach the heating element 5 in the groove 4 is to use an adhesive. Thus, according to some aspects, the at least one heating element 5 is fastened to the support section 2 in the groove 4 by means of an adhesive. There are very strong adhesives and an adhesive is a fast and cheap way of attaching the heating element/elements 5 to the support section 2. The adhesive may be thermally conductive so assist in transferring heat from the at least one heating element 5 to the support section 2. The adhesive is for example glue or a resin.

There are alternatives to attaching the at least one heating element 5 with an adhesive, such as using a clamp, cable ties or screws. According to some aspects, the at least one heating element 5 is fastened to the support section 2 in the groove 4 by means of at least one resilient element 7, the at least one resilient element 7 being clamped between the two opposing mounting flanges 3 such that it holds the at least one heating element 5 in place in the groove 4. In FIGS. 4 to 7, resilient elements 7 are illustrated as pieces of material that is resilient and which is clamped between the inner sides of the mounting flanges 3. In the illustrated examples there are two resilient elements 7 holding each heating element 5, but it may also be that one or several resilient elements 7 are used to hold a heating element 5. The resilient element 7 is preferably made of a thermally conducting material. It may also be that the heating element/elements 5 is attached with both an adhesive and resilient elements 7. By using a resilient element 7, the heating element/elements 5 may be attached in the groove 4 instantly. This is also a cheap and fast way of securing the at least one heating element 5. Another term for the resilient is restraint element because it is a resilient material that restraints the heating element 5 to the groove 4.

Using a resilient element 7 is preferably used in combination with a DIN rail standard where the mounting flanges 3 are curved, for example as the one shown in FIGS. 4 to 8. The resilient element 7 is more easily secured to curved mounting flanges 3. The DIN rails 1 can alternatively be equipped with protrusions for securing the resilient elements 7.

Both using an adhesive and at least one resilient element 7 for fastening the at least one heating element 5 may be used in an efficient way in mass producing the DIN rail 1.

The at least one heating element 5 may comprise wiring 8 for powering the at least one Positive Temperature Coefficient heater 6. The wiring 8 is, for example, arranged in the groove 4. The wiring 8 is for example arranged in the bend between the support section 2 and the mounting flanges 3 as can be seen in the examples of FIGS. 12 and 16. An advantage with arranging the wiring 8 in the groove 4 is that the wiring 8 is physically protected in the groove 4 by the mounting flanges 3. The wiring 8 is thus protected from physical damage and from getting hooked on something during handling. Another advantage is that it is visually appealing to hide the wiring 8 in the grove such that they are visually less apparent.

For simplifying mass production of the DIN rail 1, the at least one heating element 5 may be attached to the back side of the support section 2. Depending on the method to produce the DIN rail 1, it may be advantageous to arrange the at least one heating element 5 on the back side. According to some aspects, the at least one heating element is attached to the back side of the support section 2. This may also be advantageous depending on the type of standard used for the DIN rail 1. For some standards, the at least one heating element 5 may be in the way of mounting the electronic equipment when located in the groove 4. In such cases, arranging the heating element/elements 5 on the back side is advantageous. The at least one heating element 5 may for example be attached to the back side with an adhesive. Again, alternatives to attaching the at least one heating element 5 with an adhesive are using a clamp, cable ties or screws. Since the heating element/elements 5 are then arranged between the support section 2 and the surface the DIN rail 1 is attached to, it is preferred that the material of the at least one heating element 5 has a structural integrity to not be harmed when mounting the DIN rail 1. The at least one heating element may for example have an outer material of steel, silicone or a mix of silicone and silicon.

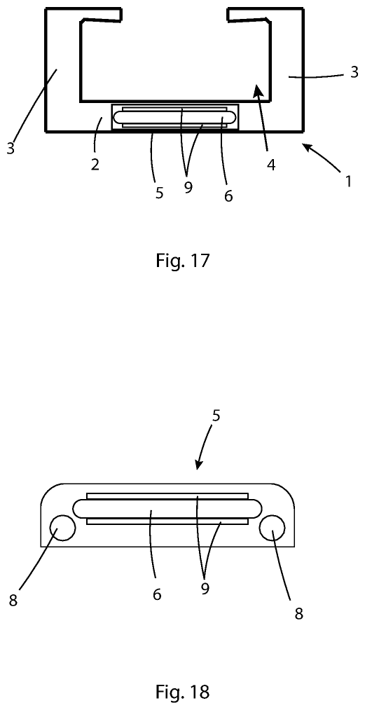

An alternative to arranging the at least one heating element in the back side 2 or in the groove 4, is to arrange it inside the material of the support section 2. An example of this is illustrated in FIG. 17, where the DIN rail 1 is a C-section DIN rail 1 with an embedded heating element. The feature is of course applicable to all DIN rail standards, not just the C-section. Thus, according to some aspects, the at least one heating element is embedded in the material of the support section 2. The support section 2 is in this case made in two layers with the at least one heating element 5 therebetween. This is advantageous especially in demanding environments where the at least one heating element 5 and/or the wiring 8 needs to be protected from the environment. This may also be a very secure alternative since a user of the DIN rail 1 will not be able to access the at least one heating element 5 or its wiring 8 if the wiring 8 is also embedded in the support section 2. Since the at least one heating element 5 is not accessible for users of the DIN rail 1, the life time of the DIN rail 1 may increase.

Both in the case when the at least one heating element 5 is arranged openly in the groove 4 or on the back side and when it is arranged embedded in the material of the support section 2, the outer surface of the at least one heating element 5 is preferably not conducting a current. The PTC heaters 6 are thus electrically insulated from the surface of the heating element/elements 5. This may be done with for example an electrically insulating material arranged around the PTC heaters 6. The electrically insulating material is preferably thermally conducting to increase heat transfer to the surface of the at least one heating element 5.

There are many ways to realize and arrange the heating element/elements 5. According to some aspects, the at least one heating element 5 comprises a plurality of heating elements 5 arranged at a distance from each other along the elongated support section 2. DIN rails 1 come at different lengths and they usually have holes 10 at regular intervals in the support section 2 for fastening to a surface using for example screws or the like. The heating elements 5 may therefore be distributed with a distance between them so that the holes 10 are accessible for fastening the rail. If the DIN rail 1 is a short one, there may be only one heating element 5 comprised at the support section 2. According to some aspects, the plurality of heating elements 5 are evenly distributed along a length of the elongated support section 2. That the heating elements 5 are evenly distributed may be advantageous in production, since there is no resetting of the distances, and it may also be visually appealing with regular intervals between the heating elements 5. If the fastening holes 10 of the support section 2 are arranged at regular intervals, the heating elements 5 may be arranged regularly between the holes 10.

There may be one or more PTC heaters 6 in a heating element 5. According to some aspects, each of the at least one heating element 5 comprises a plurality of Positive Temperature Coefficient heaters 6 distributed in the heating element 5. PTC elements can be produced in various sizes and shapes and each heating element 5 may therefore comprise one or several PTC heaters 6. For simplifying production, it may be advantageous with one PTC heater per heating element 5 but more than one may give a more even spread of heat. According to some aspects, the Positive Temperature Coefficient heaters 6 are evenly distributed along a length of the heating element 5. An advantage with this is even heat distribution in the heating element 5.

The heating element 5 can be designed in different ways to realize desired properties. According to some aspects, the at least one heating element 5 has a maximum surface temperature between 30° and 45° Celsius and preferably a maximum temperature of 40° Celsius. The temperature is to ensure a good working temperature for electrical equipment mounted in the DIN rail 1. Electrical equipment is usually made for functioning best in room temperature or slightly above room temperature. A surface temperature between 30 and 45 degrees Celsius will provide optimal working conditions for the electrical equipment.

To reach a maximum surface temperature between 30° and 45° Celsius a small PTC heater with a higher maximum temperature may be used. The temperature is then decreased as the heat is conducted through the material of the heating element 5. For example, a PTC heater with a maximum temperature of between 70° and 100° Celsius may be used. Another way of realizing a maximum surface temperature is to have several PTC heaters 6 or a larger PTC heater with a maximum temperature close to the desired surface temperature. For example, 3 PTC heaters 6 with a maximum temperature of 50° Celsius may be used to reach a surface temperature of 45° Celsius.

Since PTC heaters 6 come in many variations in size and maximum temperatures, it is up to the designer of the system to choose which PTC heaters 6 to use and how many. Depending on what standard DIN rail shape is used, different sizes and maximum temperature PTC heaters 6 may be desirable. For example, it may be advantageous to use larger PTC heaters 6 for DIN rails 1 with a wider supporting section and smaller PTC heaters 6 for more narrow DIN rails 1.

There are different ways to power a PTC heater. One way is illustrated in FIG. 18, which shows a cross section of an example heating element 5. In the illustrated example, the Positive Temperature Coefficient heaters 6 are arranged between two steel plates 9 which are arranged along a length of the heating element 5, the Positive Temperature Coefficient heaters 6 and the steel plates 9 being embedded in an electrically insulating material. In other words, the two steel plates 9 are elongated and extend through a length of the heating element 5 and between those two steel plates 9, one or more PTC heaters 6 are arranged.

Wiring 8 as show in the figures, is then connected to a respective plate to power the PTC heaters 6.

Another example of how the PTC heaters 6 may be powered is that the wires 8 going through the heating element 5 may be shaved so that they are not insulated where they abut the PTC heaters 6. In other words, the two wires 8, as can be seen in the figures, going through the at least one heating element 5 are arranged on opposite sides of the PTC heater/heaters 6 such that they abut the PTC heater/heaters 6 and in the contact area, the wires 8 are shaved to expose the conducting wires.

In the illustrated example of FIG. 17, the PTC heaters 6 are enclosed in a heat conducting material to form the heating element 5. The heat conducting material is for example aluminum or steel. In other words, the at least one heating element 5 comprises an aluminum or steel material embedded with one or more PTC heaters 6 with some kind of insulation and wiring 8. According to some aspects, the at least one heating element 5 has an elongated shape with PTC heaters 6 arranged in a row with a distance between them. According to some aspects, the at least one heating element 5 comprises two or more rows of PTC heaters 6.

The use of the DIN rail 1 according to any of the above features is to heat mounted electrical equipment, preferably in a rack cabinet or control cabinet.

For ensuring secure functionality of the DIN rail 1, it may be connected to a circuit breaker for protecting it from overload or short circuit. According to an embodiment of the disclosure, it comprises a DIN rail system comprising a DIN rail 1 comprising an elongated support section 2 with a back side and a front side, wherein the front side comprising two elongated mounting flanges 3 along opposite sides of the front side, for fastening the electrical equipment, and an elongated groove 4 therebetween. The DIN rail 1 further comprises at least one heating element 5 arranged in direct contact with the support section 2 and that the at least one heating element 5 comprises at least one Positive Temperature Coefficient heater 6. The Din rail system comprising a circuit breaker mounted to the DIN rail 1 and electrically connected to the at least one heating element 5. With a circuit breaker for the at least one heating elements 5 already attached to the DIN rail 1, the DIN rail system provides a ready to use DIN rail 1 which provides optimal working conditions for electrical equipment. The DIN rail system is thus easy to mount to a surface and connecting electricity to the circuit breaker. The DIN rail 1 of the DIN rail system can of course be according to any of the above described aspects since all of the above are combinable with a circuit breaker. The circuit breaker is designed to be fastened to the protruding parts of the DIN rail 1. According to some aspects, the circuit breaker is a Miniature Circuit Breaker, MCB and it may also be a MCCB, Molded Case Circuit Breaker. The circuit breaker is not illustrated in the figures since any standard circuit breaker may be used that is suitable to use with the at least one heating element 5 and which is mountable to the DIN rail 1.

Aspects:

Aspect 1: A DIN rail (1) for mounting of electrical equipment, the DIN rail (1) comprising an elongated support section (2) with a front side and a back side, wherein the front side comprising two elongated mounting flanges (3) along opposite sides of the front side, for fastening the electrical equipment, and an elongated groove (4) therebetween, characterized in that the DIN rail comprises at least one heating element (5) arranged in direct contact with the support section (2) and that the at least one heating element (5) comprises at least one Positive Temperature Coefficient heater (6).

Aspect 2: The DIN rail (1) according to aspect 1, wherein the at least one heating element (5) is arranged in the groove (4).

Aspect 3: The DIN rail (1) according to aspect 2, wherein the at least one heating element (5) comprises a material surrounding the at least one Positive Temperature Coefficient heater (6), the material comprises silicone and has an outer shape such that it fits into the groove (4) and is held in the groove by the mounting flanges (3).

Aspect 4: The DIN rail (1) according to aspect 2, wherein the at least one heating element (5) is fastened to the support section (2) in the groove (4) by means of at least one resilient element (7), the at least one resilient element (7) being clamped between the two opposing mounting flanges (3) such that it holds the at least one heating element (5) in place in the groove (4).

Aspect 5: The DIN rail (1) according to any preceding aspect, wherein the at least one heating element (5) is fastened to the support section (2) by means of an adhesive.

Aspect 6: The DIN rail (1) according to any one of aspects 2 to 5, wherein the at least one heating element (5) comprises wiring (8) for powering the at least one Positive Temperature Coefficient heater (6), the wiring (8) being arranged in the groove (4).

Aspect 7: The DIN rail (1) according to aspect 1 or 5, wherein the at least one heating element (5) is attached to the back side of the support section (2).

Aspect 8: The DIN rail (1) according to aspect 1, wherein the at least one heating element (5) is embedded in the material of the support section (2).

Aspect 9: The DIN rail (1) according to any preceding aspect, wherein the at least one heating element (5) comprises a plurality of heating elements (5) arranged at a distance from each other along the elongated support section (2).

Aspect 10: The DIN rail (1) according to aspect 9, wherein the plurality of heating elements (5) are evenly distributed along a length of the elongated support section (2).

Aspect 11: The DIN rail (1) according to any preceding aspect, wherein each of the at least one heating element (5) comprises a plurality of Positive Temperature Coefficient heaters (6) distributed in the heating element (5).

Aspect 12: The DIN rail (1) according to aspect 11, wherein the Positive Temperature Coefficient heaters (6) are evenly distributed along a length of the heating element (5).

Aspect 13: The DIN rail (1) according to aspect 11 or 12, wherein the Positive Temperature Coefficient heaters (6) are arranged between two steel plates (9) which are arranged along a length of the heating element (5), the Positive Temperature Coefficient heaters (6) and the steel plates (9) being embedded in an electrically insulating material.

Aspect 14: The DIN rail (1) according to any preceding aspect, wherein the heating element (5) has a maximum surface temperature between 30° and 45° Celsius and preferably a maximum temperature of 40° Celsius.

Aspect 15: Use of the DIN rail (1) according to any one of aspects 1-14, to heat mounted electrical equipment.

Aspect 16: A DIN rail system comprising a DIN rail (1) according to any one of claims 1-14, the system comprising a circuit breaker mounted to the DIN rail (1) and electrically connected to the at least one heating element (5).

Aspect 17: The DIN rail system according to aspect 16, wherein the circuit breaker is a miniature circuit breaker, MCB.

### REFERENCE LIST

1. DIN rail
2. Support section
3. Mounting flanges
4. Groove
5. Heating element
6. PTC heater
7. Resilient element
8. Wiring
9. Steel plate
10. Hole
11. Flexible sheet
   a) Upper surface
12. Positive Temperature Coefficient paint
13. Edge
14. Electrical equipment
15. Flexible insulating material
16. Terminal

1. A heating element (5) for heating electrical equipment mounted on a DIN rail (1), wherein the heating element (5) comprises an elongated flexible sheet (11) made of an electrically insulating material and a layer comprising Positive Temperature Coefficient paint (12) disposed on an upper surface (11a) of the flexible sheet (11).

2. The heating element (5) according to claim 1, wherein the Positive Temperature Coefficient paint (12) is disposed over substantially the full length of the flexible sheet.

3. The heating element (5) according to claim 1, wherein the Positive Temperature Coefficient paint (12) is disposed over a width of the flexible sheet (11) of at least 2 mm and on a central part of the flexible sheet (11).

4. The heating element (5) according to claim 1, wherein the Positive Temperature Coefficient paint is disposed over at least 75% of the width of the flexible sheet (11) and on a central part of the flexible sheet (11).

5. The heating element (5) according to claim 1, wherein the Positive Temperature Coefficient paint is disposed on multiple discrete places on the upper surface (11a) of the flexible sheet (11).

6. The heating element (5) according to claim 1, wherein the electrically insulating material comprises a dielectric material such as polyester or plastic.

7. The heating element (5) according to claim 1, wherein the flexible sheet (11) comprises one edge (13) along each side of the flexible sheet (11) and the edges on the two elongated sides are rounded on the side of the upper surface (11a).

8. The heating element (5) according to claim 1, wherein the length and width of the flexible sheet (11) are adapted such that the flexible sheet, when it is bent in an inverted U-shape along its length, fits into a groove of a DIN rail (1).

9. The heating element (5) according to claim 1, comprising wiring (8) for powering the Positive Temperature Coefficient paint (12) arranged in connection to the Positive Temperature Coefficient paint (12).

10. Method for mounting the heating element (5) according to claim 1, to a DIN rail, comprising:
bending the flexible sheet (11) such that an inverted U-shape is formed along the length of the flexible sheet, and
inserting the heating element (5) into a groove of the DIN rail (1) such that the bent flexible sheet stays in position by spring force of the bend.

11. The combination of the heating element according to claim 1 and a DIN rail, wherein the flexible sheet (11) is bent in an inverted U-shape along its length and mounted into a groove of the DIN rail (1) such that the bent flexible sheet (11) stays in position by spring force of the bend.
